(19) United States
(12) Patent Application Publication
(10) Pub. No.: US 2016/0109532 A1
(43) Pub. Date: Apr. 21, 2016

(54) SET/RESET CIRCUIT AND MAGNETIC SENSING DEVICE USING THE SAME

(71) Applicant: Voltafield Technology Corporation, Jhubei City (TW)

(72) Inventor: Nai-Chung FU, Jhubei City (TW)

(21) Appl. No.: 14/669,009

(22) Filed: Mar. 26, 2015

(30) Foreign Application Priority Data
Oct. 21, 2014 (TW) 103136369

(51) Int. Cl. G01R 33/00; G01R 33/09

(52) U.S. Cl. CPC G01R 33/0023; G01R 33/09

(57) ABSTRACT

A set/reset circuit used with a magnetoresistive sensor includes a coil, four switch units, a capacitor and a control unit. The four switch units are electrically coupled between a power supply voltage (or a reference voltage) and the coil and have variable resistances. The first end of the capacitor is electrically coupled to the power supply voltage and some of the switch units, and the second end of the capacitor is electrically coupled to the reference voltage. The control unit is electrically coupled to the four switch units and configured to receive a first pulse width modulation signal and a second pulse width modulation signal. A magnetic sensing device utilizing the abovementioned set/reset circuit is also provided.

### TECHNICAL FIELD

The present invention relates to a set/reset circuit used in a magnetic sensing device, and more particularly to a set/reset circuit having one capacitor only which is able to supply electrical power to operate the set/reset circuit and stabilize the related power supply voltage. The present invention is also related to a magnetic sensing device utilizing the abovementioned set/reset circuit.

### BACKGROUND

In recent years, magnetic sensing devices have been widely used in magnetic compass, rotary position sensing, current sensing, directional drilling, liner position measurement, yaw rate sensor and head trajectory tracking in virtual reality. Generally, a magnetic sensing device mainly includes a magnetoresistive sensor and a set/reset circuit. When an external magnetic field is applied to the magnetic sensing device, the resistance of the magnetoresistive material constituting the magnetic sensing device will change, so a user can determine the intensity of the external magnetic field according to the voltage change of the magnetoresistive material. The set/reset circuit is used to reset the align direction of the magnetic moment of the magnetoresistive material, so that the magnetic sensing device can measure the external magnetic field correctly. Under a normal circumstance, the direction of the magnetic moment of the magnetoresistive material after being reset and the direction of the magnetic moment of the magnetoresistive material after being set have a 180 degree difference.

In a conventional design, the set/reset circuit is provided with a plurality of capacitors for having a normal operation, and at least one of the capacitors is also used to stabilize the power supply voltage. However, these capacitors may cause that the set/reset circuit therefore has a relatively large circuit area and consequentially the magnetic sensing device has a relatively large circuit area. Thus, it is quite important to develop a set/reset circuit as well as a magnetic sensing device having reduced size.

### SUMMARY OF EMBODIMENTS

Therefore, one object of the present invention is to provide a set/reset circuit which can be operated by utilizing one capacitor only, wherein the capacitor is also used to stabilize the related power supply voltage.

Another object of the present invention is to provide a magnetic sensing device utilizing the abovementioned set/reset circuit.

The present invention provides a set/reset circuit used with a magnetoresistive sensor. The set/reset circuit includes a coil, a first switch unit, a second switch unit, a third switch unit, a fourth switch unit, a capacitor and a control unit. The coil has a first end and a second end. The first switch unit is electrically coupled between a power supply voltage and the first end of the coil and has a variable resistance. The second switch unit is electrically coupled between the power supply voltage and the second end of the coil and has a variable resistance. The third switch unit is electrically coupled between the second end of the coil and a reference voltage and has a variable resistance. The fourth switch unit is electrically coupled between the first end of the coil and the reference voltage and has a variable resistance. The capacitor has a first end and a second end. The first end of the capacitor is electrically coupled to the power supply voltage, the first switch unit and the second switch unit, and the second end of the capacitor is electrically coupled to the reference voltage. The control unit is electrically coupled to the first, the second, the third and the fourth switch units and configured to receive a first pulse width modulation signal and a second pulse width modulation signal.

The present invention further provides a magnetic sensing device, which includes the abovementioned set/reset circuit and a magnetoresistive sensor.

In summary, the set/reset circuit of the present invention utilizes N switch units to provide respective electrical paths with variable resistances and uses the control unit to turn on or turn off the N switch units, thereby changing the flowing direction of the current in the coil and resetting the direction of the magnetic moment of the magnetoresistive sensor in the magnetic sensing device. Additionally, the control unit is further used to control the resistances of the electrical paths of the N switch units so as to modulate the value of the current flowing in the coil. Therefore, by utilizing one capacitor only, the set/reset circuit can be operated and the power supply voltage is stabilized. Because all of the abovementioned switch units can be implemented with transistors which have component sizes much smaller than the capacitors and the control unit has a smaller circuit area due to that the operation of the switch units is less complicated, the entire circuit area of the set/reset circuit is efficiently reduced. Consequentially, the magnetic sensing device utilizing the set/reset circuit has a reduced circuit size.

### BRIEF DESCRIPTION OF THE DRAWINGS

The above embodiments will become more readily apparent to those ordinarily skilled in the art after reviewing the following detailed description and accompanying drawings, in which:

FIG. 1 is a schematic diagram of a set/reset circuit in accordance with an embodiment of the present invention;

FIG. 2 is a schematic diagram of an arrangement between the coil in FIG. 1 and a magnetoresistive sensor in accordance with an embodiment of the present invention;

FIG. 3 is an exemplary circuit diagram of the control unit in the set/reset circuit of FIG. 1 in accordance with an embodiment of the present invention;

FIG. 4 is a schematic diagram illustrating the switch units equipped with respective resistive elements; and

FIG. 5 is a schematic block diagram of a magnetic sensing device in accordance with an embodiment of the present invention.

### DETAILED DESCRIPTION OF PREFERRED EMBODIMENTS

The disclosure will now be described more specifically with reference to the following embodiments. It is to be noted that the following descriptions of preferred embodiments are presented herein for purpose of illustration and description only. It is not intended to be exhaustive or to be limited to the precise form disclosed.

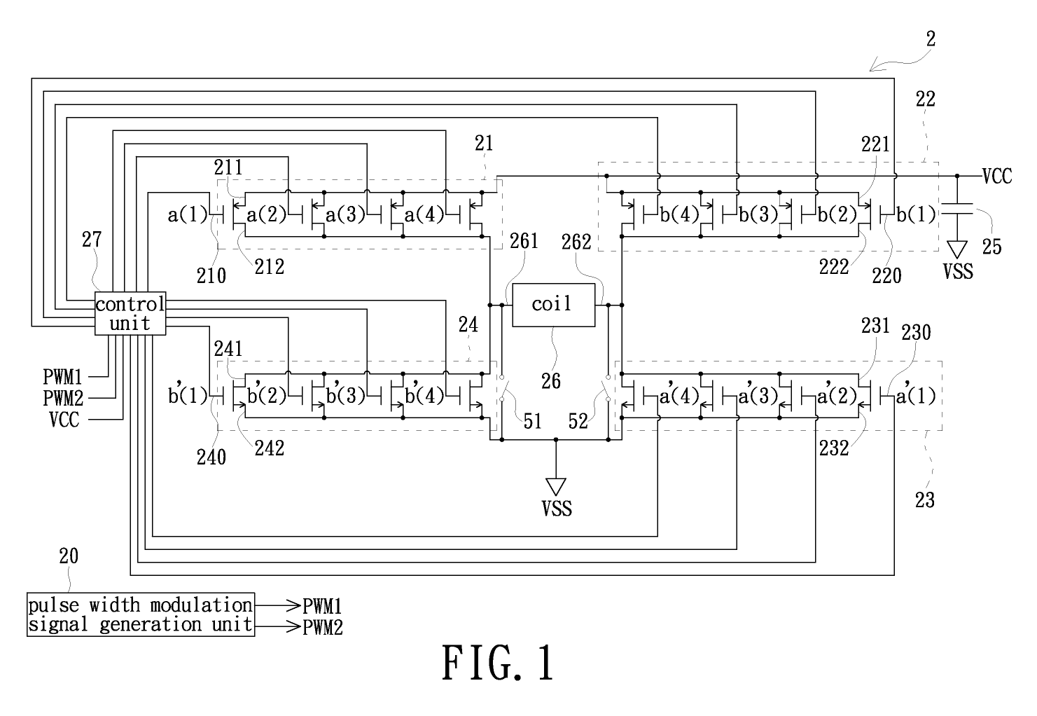

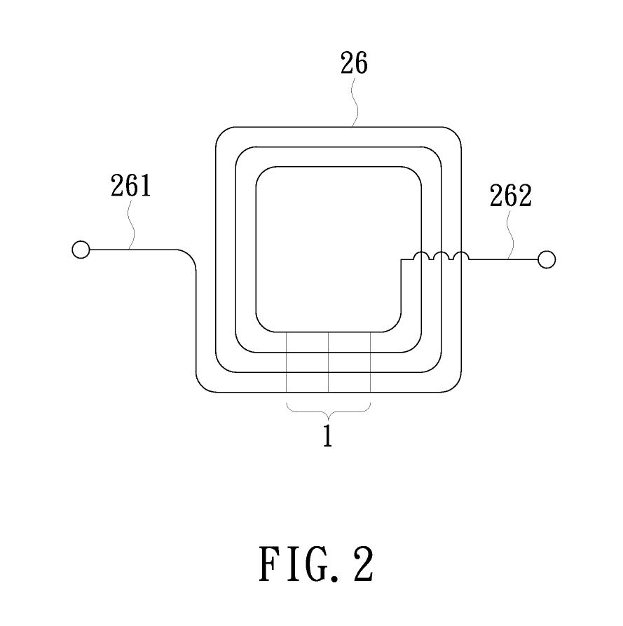

FIG. 1 is a schematic diagram of a set/reset circuit in accordance with an embodiment of the present invention. As shown in FIG. 1, the set/reset circuit 2 in the present embodiment mainly includes a plurality of switch units 21, 22, 23 and 24, a capacitor 25, a coil 26 and a control unit 27. The coil 26 has a first end 261 and a second end 262. FIG. 2 is a schematic diagram of an arrangement between the coil 26 and a magnetoresistive sensor in accordance with an embodiment of the present invention. As shown in FIG. 2, the coil 26 has a spiral structure on a plane and the magnetoresistive sensor 1 and the coil 26 are alternately arranged. Specifically, the magnetoresistive sensor 1 extends in a direction toward an innermost ring and an outermost ring of the coil 26 and the extending direction of the magnetoresistive sensor 1 is perpendicular (or substantially perpendicular) to the extending directions of the first end 261 and the second end 262 of the coil 26.

As shown in FIG. 1, one end of the capacitor 25 is electrically coupled to a power supply voltage VCC, the switch unit 21 and the switch unit 22, and the other end of the capacitor 25 is electrically coupled to a reference voltage VSS. The switch unit 21 is electrically coupled between the power supply voltage VCC and the first end 261 of the coil 26. The switch unit 21 is configured to provide a first electrical path having a first variable resistance between the power supply voltage VCC and the first end 261 of the coil 26. The switch unit 22 is electrically coupled between the power supply voltage VCC and the second end 262 of the coil 26. The switch unit 22 is configured to provide a second electrical path having a second variable resistance between the power supply voltage VCC and the second end 262 of the coil 26. The switch unit 23 is electrically coupled between the second end 262 of the coil 26 and the reference voltage VSS. The switch unit 23 is configured to provide a third electrical path having a third variable resistance between the second end 262 of the coil 26 and the reference voltage VSS. The switch unit 24 is electrically coupled between the first end 261 of the coil 26 and the reference voltage VSS. The switch unit 24 is configured to provide a fourth electrical path having a fourth variable resistance between the first end 261 of the coil 26 and the reference voltage VSS.

The control unit 27 is electrically coupled to the switch units 21˜24. The control unit 27 is configured to control the switch unit 21 and the switch unit 23 to provide the first electrical path and the third electrical path according to a pulse width modulation signal PWM1, respectively, and control the switch unit 22 and the switch unit 24 to provide the second electrical path and the fourth electrical path according to a pulse width modulation signal PWM2. In the present embodiment, the pulse enable period of the pulse width modulation signal PWM1 (i.e., the period of the pulse width modulation signal PWM1 having a high voltage level) and the pulse enable period of the pulse width modulation signal PWM2 (i.e., the period of the pulse width modulation signal PWM2 having a high voltage level) do not overlap. Specifically, when the control unit 27 controls the switch unit 21 and the switch unit 23 to provide the first electrical path and the third electrical path, respectively, the current from the power supply voltage VCC and the capacitor 25 flows to the reference voltage VSS sequentially through the first electrical path, the coil 26 and the third electrical path. Meanwhile, the magnetic field, generated by the coil 26 being supplied with electrical power, can be used to reset the direction of the magnetic moment of the magnetoresistive material of the magnetoresistive sensor 1. In the present embodiment, the aforementioned operation is referred to as either a set operation or a reset operation.

Similarly, when the control unit 27 controls the switch unit 22 and the switch unit 24 to provide the second electrical path and the fourth electrical path, respectively, the current from the power supply voltage VCC and the capacitor 25 flows to the reference voltage VSS sequentially through the second electrical path, the coil 26 and the fourth electrical path. Meanwhile, the magnetic field, generated by the coil 26 being supplied with electrical power, can also be used to reset the direction of the magnetic moment of the magnetoresistive material of the magnetoresistive sensor 1. In the present embodiment, the aforementioned operation is referred to as either a set operation or a reset operation. It is to be noted that the direction of the magnetic moment of the magnetoresistive material of the magnetoresistive sensor 1 generated by the first electrical path and the third electrical path and the direction of the magnetic moment of the magnetoresistive material of the magnetoresistive sensor 1 generated by the second electrical path and the fourth electrical path have (or substantially have) 180 degree difference.

In addition, the control unit 27 is further configured to determine the value of the power supply voltage VCC. Specifically, the control unit 27 controls the switch units 21˜24 to provide variable resistances increased with increasing value of the power supply voltage VCC. Thus, through the aforementioned control mechanism of the set operation or the reset operation by the control unit using the switch units 21˜24 the amount of the charges drawn from the power supply voltage VCC and the capacitor 25 is limited while the set/reset circuit 2 performs the set operation or the reset operation. As a result, the issue of drawing charges more than the capacitor 25 can provide is avoided, and consequentially the voltage stabilizing ability of the capacitor 25 and the voltage level of the power supply voltage VCC are maintained. It is to be noted that once the voltage level of the power supply voltage VCC is pulled down, the operations of the electronic components or devices (for example, I/O, microcontroller, memory, or other control elements) sharing the power supply voltage VCC with the set/reset circuit 2 may be greatly affected.

In the present embodiment, each one of the switch units 21˜24 includes N transistors, where N is a positive integer and N is for example four in the present illustrated embodiment. Each one of the N transistors in the switch unit 21 has a gate 210, a first source/drain 211 and a second source/drain 212. The four transistors in the switch unit 21 are configured to have their first sources/drains 211 electrically coupled to the power supply voltage VCC, their second sources/drains 212 electrically coupled to the first end 261 of the coil 26, and their gates 210 electrically coupled to the control unit 27 and from which to receive the control signals a(1)˜a(4), respectively. In the present embodiment, the four transistors in the switch unit 21 are controlled to be turned-on or turned-off according to the control signals a(1)˜a(4), respectively. Each one of the N transistors in the switch unit 22 has a gate 220, a first source/drain 221 and a second source/drain 222. The four transistors in the switch unit 22 are configured to have their first sources/drains 221 electrically coupled to the power supply voltage VCC, their second sources/drains 222 electrically coupled to the second end 262 of the coil 26, and their gates 220 electrically coupled to the control unit 27 and from which to receive the control signals b(1)˜b(4), respectively. In the present embodiment, the four transistors in the switch unit 22 are controlled to be turned-on or turned-off according to the control signals b(1)˜b(4), respectively.

Each one of the N transistors in the switch unit 23 has a gate 230, a first source/drain 231 and a second source/drain 232. The four transistors in the switch unit 23 are configured to have their first sources/drains 231 electrically coupled to the second end 262 of the coil 26, their second sources/drains 232 electrically coupled to the reference voltage VSS, and their gates 230 electrically coupled to the control unit 27 and from which to receive the control signals a′(1)˜a′(4), respectively. In the present embodiment, the four transistors in the switch unit 23 are controlled to be turned-on or turned-off according to the control signals a′(1)˜a′(4), respectively. Each one of the N transistors in the switch unit 24 has a gate 240, a first source/drain 241 and a second source/drain 242. The four transistors in the switch unit 24 are configured to have their first sources/drains 241 electrically coupled to the first end 261 of the coil 26, their second sources/drains 242 electrically coupled to the reference voltage VSS, and their gates 240 electrically coupled to the control unit 27 and from which to receive the control signals b′(1)˜b′(4), respectively. In the present embodiment, the four transistors in the switch unit 24 are controlled to be turned-on or turned-off according to the control signals b′(1)˜b′(4), respectively.

In the present embodiment, each transistor in the switch units 21 and 22 is implemented with a P-type transistor and each transistor in the switch units 23 and 24 is implemented with an N-type transistor; however, the present invention is not limited thereto.

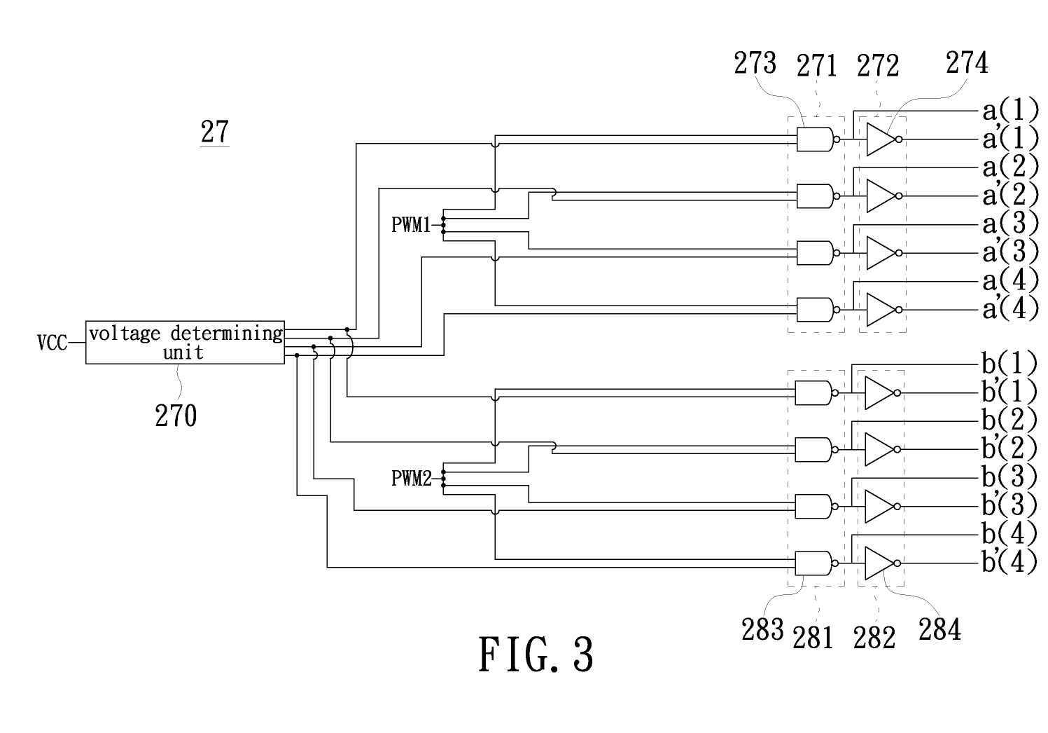

FIG. 3 is an exemplary circuit diagram of the control unit in FIG. 1 in accordance with an embodiment of the present invention. As shown in FIG. 3, the control unit 27 in the present embodiment includes a voltage determining unit 270, NAND gate groups 271 and 281, and NOT gate groups 272 and 282. The voltage determining unit 270 is configured to receive the power supply voltage VCC, determine the value of the power supply voltage VCC and accordingly output N (in the present embodiment, N=4) output signals. In the present embodiment, each output signal represents one bit data.

The NAND gate group 271 includes N (in the present embodiment, N=4) NAND gates 273. The four NAND gates 273 in the NAND gate group 271 are configured to have their first input ends for receiving the pulse width modulation signal PWM1, their second input ends for receiving the four output signals of the voltage determining unit 270 respectively, and their output ends for outputting the control signals a(1)˜a(4) respectively. The NOT gate group 272 includes N (in the present embodiment, N=4) NOT gates 274. The four NOT gates 274 in the NOT gate group 272 are configured to have their input ends electrically coupled to the output ends of the four NAND gates 273 in the NAND gate group 271 and the gates 210 of the four transistors in the switch unit 21 respectively, and their output ends for outputting the control signals a′(1)˜a′(4) and electrically coupled to the gates 230 of the four transistors in the switch unit 23 respectively.

The NAND gate group 281 includes N (in the present embodiment, N=4) NAND gates 283. The four NAND gates 283 in the NAND gate group 281 are configured to have their first input ends for receiving the pulse width modulation signal PWM2, their second input ends for receiving the four output signals of the voltage determining unit 270 respectively, and their output ends for outputting the control signals b(1)˜b(4) respectively. The NOT gate group 282 includes N (in the present embodiment, N=4) NOT gates 284. The four NOT gates 284 in the NOT gate group 282 are configured to have their input ends electrically coupled to the output ends of the four NAND gates 283 in the NAND gate group 281 and the gates 220 of the four transistors in the switch unit 22 respectively, and their output ends for outputting the control signals b′(1)˜b′(4) and electrically coupled to the gates 240 of the four transistors in the switch unit 24 respectively.

Please refer back to FIG. 1. In one embodiment, the transistors in each one of the switch units 21˜24 may have the same component size. Thus, the number of the transistors in each one of the switch units 21˜24 and that are turned on by the control unit 27 decreases with increasing value of the power supply voltage VCC. As a result, when the value of the power supply voltage VCC increases, the electrical path formed by the turned-on transistors in each one of the switch units 21˜24 has an increased resistance; and consequentially, the current flowing into the set/reset circuit 2 from the power supply voltage VCC and the capacitor 25 is reduced. In another embodiment, the transistors in each one of the switch units 21˜24 may have different component sizes. Thus, the total component size of the transistors in each one of the switch units 21˜24 and that are turned on by the control unit 27 decreases with increasing value of the power supply voltage VCC. As a result, when the value of the power supply voltage VCC increases, the electrical path formed by the turned-on transistors in each one of the switch units 21˜24 has an increased resistance; and consequentially, the current flowing into the set/reset circuit 2 from the power supply voltage VCC and the capacitor 25 is reduced. In summary, it is to be noted that the by utilizing one capacitor 25, not only the electrical power required by the set/reset circuit 2 can be provided but also the voltage level of the power supply voltage VCC is regulated.

In addition, as shown in FIG. 1, the set/reset circuit 2 may further include switches 51 and 52. The switch 51 is electrically coupled between the first end 261 of the coil 26 and the reference voltage VSS. The switch 52 is electrically coupled between the second end 262 of the coil 26 and the reference voltage VSS. The switches 51 and 52 are configured to be turned-on when the switch units 21, 22, 23 and 24 provide no electrical path, so that the current disturbance generated while the set/reset circuit 2 performs the set or reset operation can be introduced into the reference voltage VSS. Moreover, the set/reset circuit 2 may further include a pulse width modulation signal generation unit 20. The pulse width modulation signal generation unit 20 is configured to generate the pulse width modulation signals PWM1 and PWM2 and adjust the duty cycles of the pulse width modulation signals PWM1 and PWM2. Specifically, through a control of the pulse width modulation signal generation unit 20, the duty cycles of the pulse width modulation signals PWM1 and PWM2 decrease with increasing value of the power supply voltage VCC. Thus, when the set/reset circuit 2 performs the set or reset operation, the turn-on times/duration of the transistors in each one of the switch units 21˜24 decrease and consequentially the charges flowing into the set/reset circuit 2 from the power supply voltage VCC and the capacitor 25 decreases. As a result, the voltage regulator effect is achieved.

It is understood that the all the transistors in the switch unit 21 may be implemented with N-type transistors and all the transistors in the switch unit 23 may be implemented with P-type transistors if the control signals supplied to the transistors in the switch units 21 and 23 are properly modulated. Based on the same manner, all the transistors in the switch unit 22 may be implemented with N-type transistors and all the transistors in the switch unit 24 may be implemented with P-type transistors if the control signals supplied to the transistors in the switch units 22 and 24 are properly modulated.

In addition, it is to be noted that the NOT gate groups 272, 282 in the control unit 27 of FIG. 3 can be omitted when all of the transistors in the switch units 21˜24 are implemented with P-type transistors. Correspondingly, the output end of each NAND gate 273 in the NAND gate group 271 in FIG. 3 is electrically coupled to the gate of one of the transistors in the switch unit 21 and the gate of one of the transistors in the switch unit 23; and the output end of each NAND gate 283 in the NAND gate group 281 in FIG. 3 is electrically coupled to the gate of one of the transistors in the switch unit 22 and the gate of one of the transistors in the switch unit 24.

Alternatively, it is to be noted that the control unit 27 in FIG. 3 is configured not to output the control signals a(1)˜a(4) and b(1)˜b(4) when all of the transistors in the switch units 21˜24 are implemented with N-type transistors. Correspondingly, the output end of each NOT gate 274 in the NOT gate group 272 in FIG. 3 is electrically coupled to the gate of one of the transistors in the switch unit 21 and the gate of one of the transistors in the switch unit 23; and the output end of each NOT gate 284 in the NOT gate group 282 in FIG. 3 is electrically coupled to the gate of one of the transistors in the switch unit 22 and the gate of one of the transistors in the switch unit 24.

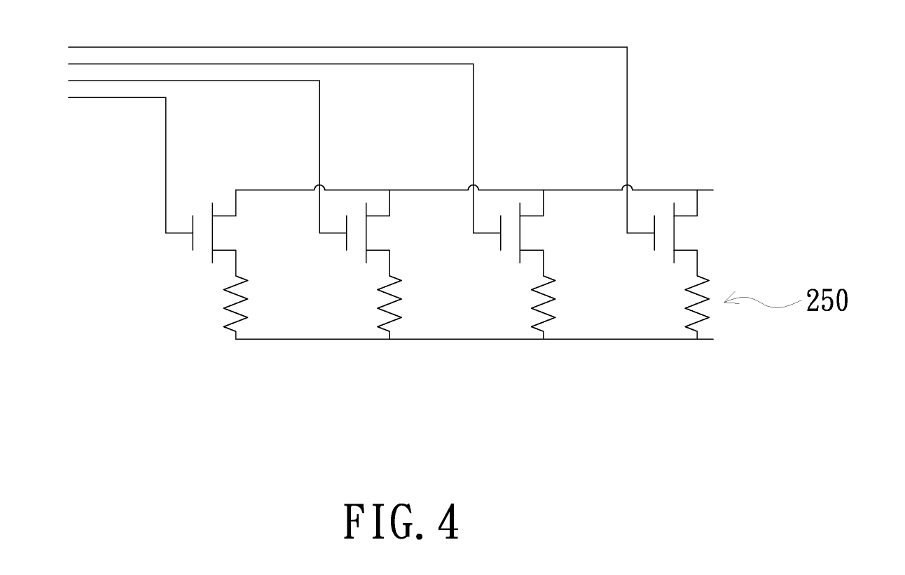

Please refer to FIGS. 1 and 4. The switch units 21˜24 in the present embodiment may further include a plurality of resistive elements 250, which are connected to the conductive loops of the transistors respectively. In one embodiment, the resistive elements 250 may be connected between the switch units 21˜24 and the coil 26. In another embodiment, the resistive elements 250 may be connected between the switch units 21, 22 and the power supply voltage VCC and between the switch units 23, 24 and the reference voltage VSS. In still another embodiment, some of the resistive elements 250 may be connected to the coil 26 and the remaining resistive elements 250 are connected to either the power supply voltage VCC or the reference voltage VSS.

In one embodiment, the resistive elements 250 may have the same resistance and the number of the transistors in each one of the switch units 21˜24 and turned on by the control unit 27 decreases with increasing value of the power supply voltage VCC. Thus, the electrical path formed by the resistive element 250 corresponding to the turned-on transistors in each one of the switch units 21˜24 has an increased resistance; and consequentially, the current flowing into the set/reset circuit 2 from the power supply voltage VCC and the capacitor 25 is reduced. In another embodiment, the resistive elements 250 in each one of the switch units 21˜24 may have different resistances. Thus, the control unit 27 may select the transistor connected to the resistive element 250 having the maximum resistance to be turned on in each one of the switch units 21˜24 when the power supply voltage VCC has an increased value. As a result, the current flowing into the set/reset circuit 2 from the power supply voltage VCC and the capacitor 25 is reduced.

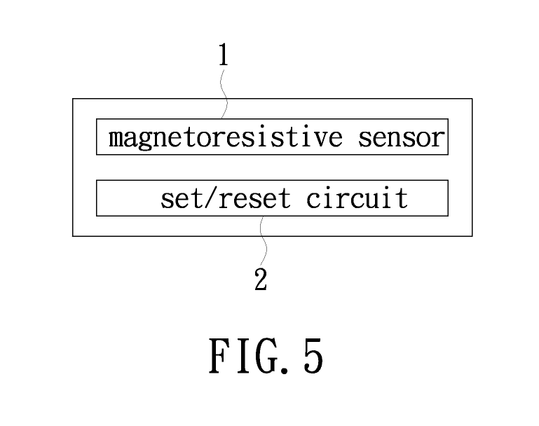

FIG. 5 is a schematic block diagram of a magnetic sensing device in accordance with an embodiment of the present invention. As shown, the magnetic sensing device in the present embodiment includes the magnetoresistive sensor 1 and the set/reset circuit 2; wherein it is to be noted that the set/reset circuit 2 may have various implementations which have been described previously. Please refer to FIG. 2 for the arrangement between the magnetoresistive sensor 1 and the set/reset circuit 2, and no redundant detail is to be given herein.

In summary, the set/reset circuit of the present invention utilizes a plurality of switch units to provide respective electrical paths with variable resistances and uses the control unit to turn on or turn off the plurality of switch units, thereby changing the flowing direction of the current in the coil and resetting the direction of the magnetic moment of the magnetoresistive sensor in the magnetic sensing device. Additionally, the control unit is further used to control the resistances of the electrical paths of the N switch units so as to modulate the value of the current flowing in the coil. Therefore, by utilizing one capacitor only, the set/reset circuit can be operated and the power supply voltage is stabilized. Because all of the abovementioned switch units can be implemented with transistors which have component sizes much smaller than the capacitors and the control unit has a smaller circuit area due to that the operation of the switch units is less complicated, the entire area of the set/reset circuit is efficiently reduced. Consequentially, the magnetic sensing device utilizing the set/reset circuit has a reduced circuit size.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A set/reset circuit used with a magnetoresistive sensor, the set/reset circuit comprising:
a coil, having a first end and a second end;
a first switch unit, electrically coupled between a power supply voltage and the first end of the coil and having a variable resistance;
a second switch unit, electrically coupled between the power supply voltage and the second end of the coil and having a variable resistance;
a third switch unit, electrically coupled between the second end of the coil and a reference voltage and having a variable resistance;
a fourth switch unit, electrically coupled between the first end of the coil and the reference voltage and having a variable resistance;
a capacitor, having a first end and a second end, wherein the first end of the capacitor is electrically coupled to the power supply voltage, the first switch unit and the second switch unit, and the second end of the capacitor is electrically coupled to the reference voltage; and
a control unit, electrically coupled to the first, the second, the third and the fourth switch units and configured to receive a first pulse width modulation signal and a second pulse width modulation signal.

2. The set/reset circuit according to claim 1, wherein each one of the first, the second, the third and the fourth switch units comprises N transistors, the turn-on or turn-off of the transistors are controlled by the control unit so as to modulate the variable resistances of the first, the second, the third and the fourth switch units.

3. The set/reset circuit according to claim 2, wherein each one of the first, the second, the third and the fourth switch units further comprises a plurality of resistive elements, and the resistive elements are connected to conductive loops of the transistors, respectively.

4. The set/reset circuit according to claim 1, wherein the resistance of the transistor, turned on by the control unit, in each one of the first, the second, the third and the fourth switch units increases with increasing value of the power supply voltage.

5. The set/reset circuit according to claim 1, further comprising:
a first switch, electrically coupled between the first end of the coil and the reference voltage; and
a second switch, electrically coupled between the second end of the coil and the reference voltage,
wherein the first and the second switches are configured to be turned-on when no electrical path is provided by the first, the second, the third and the fourth switch units.

6. The set/reset circuit according to claim 1, further comprising:
a pulse width modulation signal generation unit, configured to generate the first and the second pulse width modulation signals and adjust duty cycles of the first and the second pulse width modulation signals.

7. The set/reset circuit according to claim 6, wherein the pulse width modulation signal generation unit controls the first and the second pulse width modulation signals to have duty cycles decreased with increasing value of the power supply voltage.

8. The set/reset circuit according to claim 1, wherein the first, the second, the third and the fourth switch units are control by the control unit, and at least one of the variable resistance and a turn-on time of the first, the second, the third and the fourth switch units is modulated according to the first and the second pulse width modulation signals.

9. The set/reset circuit according to claim 1, wherein the capacitor is configured to provide an electrical power required by the set/reset circuit and to stabilize a voltage level of the power supply voltage.

10. A magnetic sensing device, comprising:
a magnetoresistive sensor; and
a set/reset circuit, comprising:
a coil, having a first end and a second end;
a first switch unit, electrically coupled between a power supply voltage and the first end of the coil and having a variable resistance;
a second switch unit, electrically coupled between the power supply voltage and the second end of the coil and having a variable resistance;
a third switch unit, electrically coupled between the second end of the coil and a reference voltage and having a variable resistance;
a fourth switch unit, electrically coupled between the first end of the coil and the reference voltage and having a variable resistance;
a capacitor, having a first end and a second end, wherein the first end of the capacitor is electrically coupled to the power supply voltage, the first switch unit and the second switch unit, and the second end of the capacitor is electrically coupled to the reference voltage; and
a control unit, electrically coupled to the first, the second, the third and the fourth switch units and configured to receive a first pulse width modulation signal and a second pulse width modulation signal.

11. The magnetic sensing device according to claim 10, wherein each one of the first, the second, the third and the fourth switch units comprises N transistors, the turn-on or turn-off of the transistors are controlled by the control unit so as to modulate the variable resistances of the first, the second, the third and the fourth switch units.

12. The magnetic sensing device according to claim 11, wherein each one of the first, the second, the third and the fourth switch units further comprises a plurality of resistive elements, and the resistive elements are connected to conductive loops of the transistors, respectively.

13. The magnetic sensing device according to claim 10, wherein the resistance of the transistor, turned on by the control unit, in each one of the first, the second, the third and the fourth switch units increases with increasing value of the power supply voltage.

14. The magnetic sensing device according to claim 10, further comprising:
a first switch, electrically coupled between the first end of the coil and the reference voltage; and
a second switch, electrically coupled between the second end of the coil and the reference voltage,
wherein the first and the second switches are configured to be turned-on when no electrical path is provided by the first, the second, the third and the fourth switch units.

15. The magnetic sensing device according to claim 10, further comprising:
a pulse width modulation signal generation unit, configured to generate the first and the second pulse width modulation signals and adjust duty cycles of the first and the second pulse width modulation signals.

16. The magnetic sensing device according to claim 15, wherein the pulse width modulation signal generation unit controls the first and the second pulse width modulation signals to have duty cycles decreased with increasing value of the power supply voltage.

17. The magnetic sensing device according to claim 10, wherein the first, the second, the third and the fourth switch units are control by the control unit, and at least one of the variable resistance and a turn-on time of the first, the second, the third and the fourth switch units is modulated according to the first and the second pulse width modulation signals.

18. The magnetic sensing device according to claim 10, wherein the capacitor is configured to provide an electrical power required by the set/reset circuit and to stabilize a voltage level of the power supply voltage.
